(19) United States
(12) Patent Application Publication
(10) Pub. No.: US 2007/0280402 A1
(43) Pub. Date: Dec. 6, 2007

(54) Solid-state image sensor

(75) Inventors: Yuzo Otsuru, Anpachi-gun (JP); Kazutaka Itsumi, Kuwana-shi (JP); Shinichiro Izawa, Motosu-shi (JP); Akihiro Kuroda, Anpachi-gun (JP)

Correspondence Address: OLIFF & BERRIDGE, PLC, P.O. BOX 19928, ALEXANDRIA, VA, 22320, US

(73) Assignee: SANYO ELECTRIC CO., LTD., OSAKA (JP)

(21) Appl. No.: 11/785,874

(22) Filed: Apr. 20, 2007

(30) Foreign Application Priority Data
Apr. 26, 2006 (JP) 2006-122072

(51) Int. Cl. G11C 27/04

(52) U.S. Cl. 377/60

(57) ABSTRACT

A mixing of color that follows mixing of horizontally adjoining information charges corresponding to different colors is minimized during an operation for adding information charges of a plurality of pixels in a horizontal direction and during a high-speed horizontal transfer operation in a horizontal CCD shift register of a CCD image sensor. An impurity is used for forming barrier regions having a shallow channel potential among the barrier regions and storage regions that constitute transfer stages of the horizontal CCD shift register. The concentration of the impurity is established separately in a main portion, which is composed of transfer stages that are connected to the output ends of vertical CCD shift registers, and in a dummy portion, which connects the main portion with an output section and has a width that gradually decreases towards the output section. The barrier potential is therefore also established separately in the main portion and the dummy portion. The barrier potential is set to be high in the main portion, and the overflow of information charges into adjoining wells is minimized during the addition operation. The transfer length may be longer in the dummy portion, in which the barrier potential is limited and the fringe electric field is increased, ensuring efficient transfer during high-speed horizontal transfer.

### CROSS-REFERENCE TO RELATED APPLICATION

The priority application number JP2006-122072 upon which this patent application is based is hereby incorporated by the reference.

### BACKGROUND OF THE INVENTION

1. Field of the Invention

The present invention relates to a solid-state image sensor provided with a horizontal CCD shift register and particularly relates to improvements in the characteristics of the horizontal transfer operation for information charges.

2. Description of the Related Art

Digital still cameras, video cameras, and other imaging apparatuses having built-in CCD image sensors or other solid-state image sensors have been widely used in recent years. Such CCD image sensors may, e.g., be frame-transfer type and interline-transfer type.

FIG. 1 is a structural diagram of a frame-transfer CCD image sensor 2. The CCD image sensor 2 is configured with an imaging section 2i, a storage section 2s, a distribution section 2t, a horizontal transfer section 2h, and an output section 2d. The imaging section 2i, storage section 2s, and the distribution section 2t are all composed of a plurality of vertical CCD shift registers positioned in parallel.

The bits of the vertical CCD shift registers of the imaging section 2i constituting the respective light-receiving pixels of the image sensor. The information charges accumulated in each of the light-receiving pixels are vertically transferred at high speed from the imaging section 2i to the storage section 2s by a frame-transfer operation during the exposure period.

In CCD image sensors used to capture color images, a color filter array composed of red (R), green (G), blue (B) or the like is positioned to correspond to the light-receiving pixels positioned in a matrix in the imaging section 2i. For example, rows are formed in which R and G are arranged in an alternating fashion, and rows are formed in which B and R are arranged in an alternating fashion.

The information charges stored in the storage section 2s are line-transferred each time the horizontal transfer section 2h finishes the horizontal transfer of the information charges of one row to the output section 2d. The CCD image sensor 2 is structured so that the distribution section 2t is disposed between the storage section 2s and the horizontal transfer section 2h. The distribution section 2t functions to separate the information charges of each row output from the storage section 2s into groups of information-charge packet groups of odd-numbered columns and information-charge packet groups of even-numbered columns. The distribution section 2t then transfers the separated information charges in sequence to the horizontal transfer section 2h. A CCD image sensor 2 having such a distribution section 2t is described in, e.g., Japanese Laid-open Patent Application No. 2006-073988.

The horizontal transfer section 2h is composed of a horizontal CCD shift register. The information charges that were vertically transferred from the storage section 2s through the distribution section 2t are horizontally transferred to the output section 2d by the horizontal transfer section 2h.

The output section 2d receives the information charges output from the horizontal transfer section 2h in 1-bit units in a region having a floating-diffusion (FD) region. The output section 2d converts the information charges into a voltage value that is output as an image signal. The electric potential change in the FD region in accordance with the information charge can be increased by reducing the capacitance associated with the FD region. The FD region is therefore generally made small.

The horizontal CCD shift register that constitutes the horizontal transfer section 2h is composed of: a main portion 2m that contains bit groups positioned to correspond to the columns of the imaging section 2i or the storage section 2s; and a dummy portion 2e that is an extension extending from the output end of the main portion 2m. The horizontal dimensions of the transfer stage in the main portion 2m are minimized to correspond to the horizontal pitch of the pixels, whereas the channel width of the horizontal CCD shift register in the main portion 2m is set to be large enough to maintain the charge handling capability. On the other hand, the FD region is made small, as described above. A gap is therefore formed between the main portion 2m and the FD region due to the dimensions of the channel width. Accordingly, the dummy portion 2e is configured so that the width of the charge-transfer channel gradually narrows from the main portion 2m towards the FD region of the output section 2d. The dummy portion 2e bridges the gap between the main portion 2m and the FD region, whereby improvements in the characteristics of information-charge transfer to the FD region are achieved.

The horizontal CCD shift register has an buried-channel structure. N-wells, i.e., N-type diffusion layers, are formed on P wells (PW), i.e., P-type diffusion layers, which are formed within an N-type semiconductor substrate in the transfer-channel region (the charge-transfer region) of the horizontal CCD shift register.

In the transfer-channel region of the horizontal CCD shift register, each discrete region capable of controlling the channel potential independently of adjoining regions using a transfer clock applied to transfer electrodes is referred to as an “element region.” A storage region and a barrier region that have different channel potentials are provided to each of the element regions and are arranged in the row direction. Specifically, transfer electrodes (first poly-Si electrodes) formed of a first layer of polysilicon (referred to below as first poly-Si layer) and transfer electrodes (second poly-Si electrodes) formed of a second layer of polysilicon (referred to below as the second poly-Si layer) are arranged in an alternating fashion on the transfer-channel region. One pair of transfer electrodes composed of one first poly-Si electrode and one second poly-Si electrode is deposited to each of the element regions. Each of the pairs of transfer electrodes on the element regions is applied one transfer clock and constitutes a single transfer stage. The first poly-Si electrode is positioned on the downstream side of charge transfer in each transfer stage. The transfer-channel region below the first poly-Si electrode forms a storage region having a channel potential that is deeper than the channel potential below the second poly-Si electrode. Meanwhile, the transfer-channel region below the second poly-Si electrode, which is positioned farther upstream than the first poly-Si electrode, forms a barrier region having a potential that is shallower than the storage region and prevents reverse flow of information charges from the storage region of the same transfer stage to the transfer stage upstream.

The difference between the channel potential of the storage region and the barrier region is formed by implanting P-type impurities into the N-wells of the transfer-channel regions between the first poly-Si electrodes. In the manufacturing process of the CCD image sensor 2, the impurities used to form this barrier are implanted using an ion-implantation mask formed on the substrate after the first poly-Si layer laid on the substrate has been patterned and the first poly-Si electrodes have been formed. This mask is formed by, e.g., patterning a photoresist applied to the substrate.

In conventional manufacturing methods, the apertured part of the mask is opened on both the main portion 2m and the dummy portion 2e. The respective barrier regions of the main portion 2m and the dummy portion 2e are formed in a common ion-implantation step using the mask. Specifically, the first poly-Si electrodes within the mask aperture inhibit ion implantation in the N-wells, and P-type impurities are therefore selectively introduced into the N-wells between the first poly-Si electrodes, whereupon the barrier regions are formed. After the barrier regions have been formed, the second poly-Si electrodes are formed.

The horizontal transfer section 2h may be configured so that the respective information charges of the odd-numbered columns and the even-numbered columns that have been separated and read are horizontally transferred after being added and synthesized in groups of several pixels, whereby reductions in horizontal transfer speed can be achieved. A driving method for separating and reading the information charges, which are in rows in which the information charges corresponding to R and G are arranged in an alternating fashion, from the storage section 2s to the horizontal transfer section 2h and for adding the pixels in the horizontal direction in the horizontal transfer section 2h will be described using FIG. 2.

FIG. 2 is a schematic view that shows the potential wells in the main portion 2m of a horizontal CCD shift register and the information charges stored in the potential wells. The positions of the transfer electrodes of the horizontal transfer section 2h along the charge-transfer channel are shown in the upper part of FIG. 2. The storage states of the channel potentials and the information charges below the transfer electrodes are shown in a vertical arrangement ranging from time t₁ to time t₄ below. As for the transfer electrodes, first poly-Si electrodes 4-1 and second poly-Si electrodes 4-2 are positioned in an alternating fashion, and a shared transfer clock is applied to the first poly-Si electrode 4-1 and second poly-Si electrode 4-2, which constitute an adjoining pair, as described above. The transfer electrodes are configured to be capable of driving in, e.g., six phases of transfer clocks φ₁ though φ₆ when additive synthesis is performed in the horizontal direction for every group of three pixels (three-pixel addition). The transfer-electrode pairs corresponding to each phase are designated by the symbols HS1 through HS6, respectively. Changes in the depth of the channel potential along the charge-transfer channel in FIG. 2 are designated by a solid line 5. The channel potential is positive in the downward direction. Portions where the solid line descends are potential wells that can store information charges (shown by the diagonal lines) composed of electrons. The potential wells are formed in the storage regions of the first poly-Si electrodes 4-1. The direction of horizontal transfer is towards the left of FIG. 2.

In the horizontal addition operation, R information charges 6 are read to the potential wells below the transfer electrodes HS1, HS3, HS5 of the main portion 2m (time t₁). The information charges 6 below HS3 and HS5 are moved below HS1, and information charges 8 are generated from the additive synthesis of groups of three R information charges 6 (time t₂). G information charges 10 are next read to the potential wells below the transfer electrodes HS2, HS4, HS6 (time t₃). The information charges 10 below HS4 and HS6 are moved beneath HS2, and information charges 12 are generated from the additive synthesis of groups of three G information charges 6. The addition of the G information charges can be performed in a state in which the R information charges 8 added on the main portion 2m are retained below the transfer electrode HS1. After the addition of the G information charges, the horizontal CCD shift register is driven so that the R information charges 8 and the G information charges 12 are stored alternately in every third potential well of the main portion 2m (time t₄). The horizontal transfer section 2h then horizontally transfers the added information charges 8, 12, which are output to the output section 2d by way of the dummy portion 2e.

Information charges corresponding to a plurality of pixels are thus mixed together, whereby the image signals are strengthened. Image signals of an adequate level can therefore be obtained without underexposure even when imaging a dark photographic subject. The number of pixels that are horizontally transferred is also reduced, and high-speed horizontal transfer can be realized.

In the horizontal pixel additions described above, additive synthesis of the G information charges is performed on the main portion 2m while the additively synthesized R information charges 8 are retained in the horizontal CCD shift register. Information charges stored in adjoining potential wells and corresponding to different colors may be mixed together at this point due to the effects of the coupling capacity between transfer electrodes. Mixture between information charges corresponding to different colors may also occur due to a decrease in the transfer efficiency during the high-speed horizontal transfer operation to the output section 2d. Such mixtures of information charges are observed as color mixing in the color image based on the image signals output from the CCD image sensor 2. Therefore the mixture of information charges have resulted in reduced quality (the color reproducibility) of the images.

FIG. 3 is a schematic view for describing the generation of color mixing in the additive synthesis operation for the information charges in the main portion 2m. FIG. 3 has the same format as FIG. 2 and shows the storage state of the information charges and the channel potentials below the transfer electrodes HS1 through HS6 at time t₃, in which the G information charges 10 of the even-numbered columns are read to the main portion 2m, and at a time tₘ during the process of adding together the G information charges 10-1 through 10-3 that were read at time t₃. At time t₃, the additively-synthesized R information charges 8 are stored in potential wells 14 below HS1, and the G information charges 10-1 through 10-3 are stored in potential wells 16-1 through 16-3 below HS2, HS4, and HS6, respectively. The potential wells are formed in the storage regions, as described above. Mutually adjoining potential wells are separated by potential barriers 18 formed by the barrier regions. The difference in channel potentials between the storage region and the barrier region of each of the transfer electrodes in this instance is designated as “the barrier potential-difference φ_{B}.” The information charges 10-2, 10-3 in this state are then transferred in order in the direction of horizontal transfer, moved to the potential wells below HS2, and additively synthesized with the information charges 10-1. In the state at the time tₘ shown in FIG. 3, the transfer clocks applied to HS4, HS6 have been changed from the on-voltage to the off-voltage, whereby the channel potential below HS4 and HS6 becomes shallow and the information charges 10-2, 10-3 give the appearance of being moved to the potential wells below HS3, HS5. The information charges 10-2, 10-3 move in accordance with the electric potential gradient from the storage regions below HS4, HS6 towards the potential wells below HS3, HS5. Here, φ₆₆ is the difference in channel potentials at this point between the storage regions below the transfer electrodes to which an off-voltage is applied and the barrier regions below the transfer electrodes to which an on-voltage is applied.

In the movement operation for the information charges 10-2, 10-3 at time tₘ, the potential wells 14 that store the R information charges 8 below HS1 are also made shallower in accordance with the change in the channel potential below HS6 due to the coupling capacitance between transfer electrodes, and a phenomenon may occur in which the R information charges 8 retained in the potential wells 14 overflow into the adjoining potential wells 16-1. In particular, the amount of the information charges 8 stored in the potential wells 14 increases due to additive synthesis, and overflow therefore readily occurs due to the effects of the potential wells becoming shallower. Color mixing may thus occur during the additive synthesis operation in the main portion 2m.

FIG. 4 is a schematic view for describing the generation of color mixing during the high-speed horizontal transfer operation. FIG. 4 has the same format as FIG. 2. The high-speed horizontal transfer operation, which is driven in three phases, is executed in the state shown at time t₄ in FIG. 2; i.e., a state in which the R information charges 8 and the G information charges 12 are alternately stored in every third potential well of the main portion 2m. FIG. 4 shows the storage states of the information charges and the channel potentials below the transfer electrodes HS1 through HS6 at respective points in time before and after the movement of the information charges in the horizontal CCD shift register that is driven in three phases. At time t_{H1}, φ₁, φ₂, φ₄, and φ₅ are in an on-voltage state, φ₃ and φ₆ are in an off-voltage state, the G information charges 12 are stored in potential wells 20 below HS2, and the R information charges 8 are stored in potential wells 22 below HS5. At time t_{H2}, φ₂ and φ₅ change from the state at time t_{H1} to an off-voltage state, and the channel potentials become shallower in the storage regions below HS2, HS5, which had previously been in the state of potential wells. A channel potential gradient is thereby formed from the storage regions below HS2 towards potential wells 24 formed below HS1, and the information charges 12 move from the storage regions below HS2 to the potential wells 24. A channel potential gradient is also formed from the storage regions below HS5 towards potential wells 26 formed below HS4, and the information charges 8 move from the storage regions below HS5 to the potential wells 26. When the transfer clocks at this point have a high frequency, the transfer clocks may switch between on and off before the information charges 12 move completely from below HS2 to below HS1, for example, and the storage regions of HS2 may return to a potential well state in which some of the information charges 12 remain in the storage regions below HS2. The residual information charge will be mixed with the succeeding information charges 8 that will be transferred to the storage regions of HS2, and color mixing may result.

The transfer efficiency may differ between the main portion 2m and the dummy portion 2e. One of the reasons that can be suggested for this difference is that, e.g., the arrangement pitch Lₚ of the transfer electrode pairs may be larger in the dummy portion 2e than in the main portion 2m. The enlargement of Lₚ in the dummy portion 2e corresponds to the fact that the width W of the charge-transfer channel is narrower in the dummy portion 2e than in the main portion 2m, as described above. Specifically, the transfer-channel regions below the transfer electrodes of the dummy portion 2e are established so that a horizontal dimension L_{S} of the storage regions is larger than in the main portion 2m in order for the amount of storage charge to be maintained in response to the reduced value of the width W in the dummy portion 2e. As a result, Lₚ increases in the dummy portion 2e, and the transfer length of the information charges increases relative to the main portion 2m. The transfer efficiency may therefore be lower than in the main portion 2m.

Color mixing during the additive synthesis operation for the information charges in the main portion 2m can be minimized by increasing the barrier potential-difference φ_{B}. Color mixing during the high-speed horizontal transfer operation, on the other hand, can be minimized by increasing the electric-potential difference φ_{Δ} and the fringe electric field. However, the sum of φ_{B} and φ_{Δ} is determined in accordance with the amplitude of the transfer clocks, and therefore a trade-off must be made between φ_{B} and φ_{Δ} in situations where the amplitude of the transfer clocks needs to be small from the standpoint of reducing electrical consumption and other issues. φ_{B} and φ_{Δ} cannot both be large at the same time in such situations. Problems have accordingly arisen due to the difficulties encountered in maintaining good image quality with minimal color mixing while high-speed horizontal transfer is enabled.

### SUMMARY OF THE INVENTION

The present invention provides a solid-state image sensor that enables horizontal transfer at high speeds, minimizes color mixing, and yields good image quality.

A solid-state image sensor according to the present invention comprises a plurality of vertical CCD shift registers that are arranged in a row direction for transferring in a column direction information charges generated according to incident light; a horizontal CCD shift register for transferring in the row direction the information charges output from the vertical CCD shift registers, in which a charge-transfer region is formed from a plurality of element regions arranged in the row direction, and in which adjoining element regions can, independently of one another, control a channel potential using a transfer clock; and an output section for converting the information charges output from the horizontal CCD shift register into voltage signals. The element regions of the horizontal CCD shift register have a storage region positioned on a downstream side of charge transfer, and a barrier region positioned on an upstream side thereof and having a channel potential that is shallower than in the storage region. The horizontal CCD shift register has a main portion having a bit group connected to output ends of the plurality of vertical CCD shift registers; and an extension portion for transferring to the output section the information charges output from the main portion; and the channel potential of the barrier region is different in the main portion and in the extension portion.

### BRIEF DESCRIPTION OF THE DRAWINGS

FIG. 1 is a structural diagram of a frame-transfer CCD image sensor used for describing the prior art;

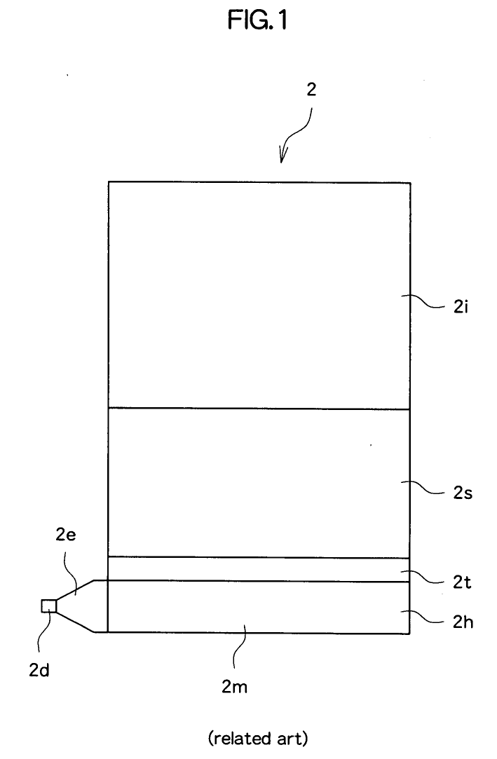

FIG. 2 is a schematic view that shows the potential wells and the information charges stored in the potential wells in the main portion of a horizontal CCD shift register during the additive-synthesis operation in the horizontal direction;

FIG. 3 is a schematic view for describing the generation of color mixing in the additive-synthesis operation for the information charges in the main portion;

FIG. 4 is a schematic view for describing the occurrence of color mixing in the high-speed horizontal transfer operation;

FIG. 5 is a schematic structural diagram of a frame-transfer CCD image sensor according to an embodiment of the present invention;

FIGS. 6A through 6C are schematic sectional top views of the image sensor and describe the steps for forming the barrier regions of the horizontal CCD shift register of the embodiment of the present invention;

FIG. 7 is a schematic view for describing the aspects of the addition operation for the information charges of three pixels, which are arranged horizontally in the horizontal transfer section of the embodiment of the present invention; and

FIG. 8 is a schematic view for describing the aspects of the high-speed horizontal transfer operation in the horizontal transfer section of the embodiment of the present invention.

### DESCRIPTION OF THE PREFERRED EMBODIMENTS

An embodiment of the present invention will be described below with reference to the drawings.

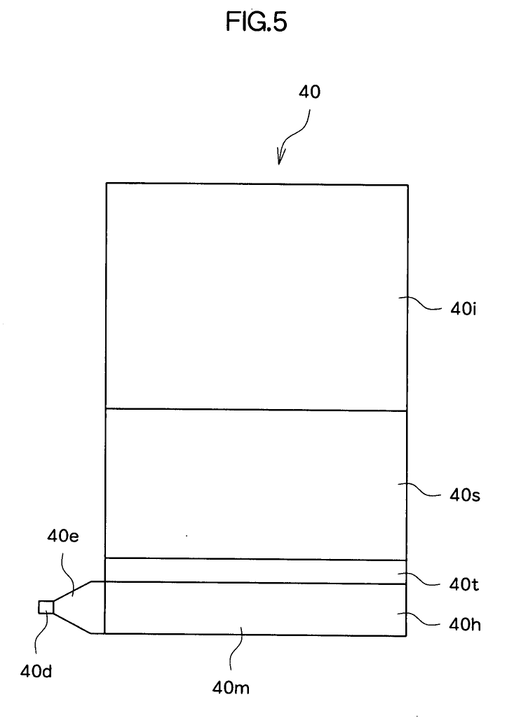

FIG. 5 is a schematic structural diagram of a frame-transfer CCD image sensor 40 according to the embodiment. The CCD image sensor 40 is configured with an imaging section 40i, a storage section 40s, a distribution section 40t, a horizontal transfer section 40h, and an output section 40d. The imaging section 40i, the storage section 40s, and the distribution section 40t are all composed of a plurality of vertical CCD shift registers. The vertical CCD shift registers are configured with a plurality of charge-transfer channel regions positioned in parallel and extending vertically, and with a plurality of transfer electrodes positioned in parallel and extending horizontally. Each bit of the vertical CCD shift registers includes the plurality of adjacently disposed transfer electrodes and forms, and potential wells for storing information charges are formed one at a time by the voltage applied to the transfer electrodes.

The bits of the vertical CCD shift registers of the imaging section 40i constitute the respective light-receiving pixels of the image sensor. The bits receive light from the photographic subject during the exposure period and generate information charges that correspond to the amount of light received and that are accumulated in potential wells. Once the exposure period has ended, the information charges are vertically transferred at high speed from the imaging section 40i to the storage section 40s by a frame-transfer operation.

The purpose of the CCD image sensor 40 is to create color images. Bayer-array color filters, for example, are positioned to correspond to the light-receiving pixels positioned in a matrix in the imaging section 40i. Rows in which R and G are arranged in an alternating fashion and rows in which B and R are arranged in an alternating fashion can thereby be formed in the imaging section 40i. Light passing through the color filters positioned thereon impinges on the light-receiving pixels, and information charges are accumulated. These information charges correspond to the amount of the incident-light component corresponding to the transparency wavelength of the color filter.

The vertical CCD shift registers of the storage section 40s are shielded from light so that the information charges transferred from the imaging section 40i can be preserved. The storage section 40s performs a line-transfer operation and moves the information charges towards the horizontal transfer section 40h each time the horizontal transfer section 40h finishes the horizontal transfer of one row of information charges to the output section 40d.

The distribution section 40t is provided between the storage section 40s and the horizontal transfer section 40h. The distribution section 40t is configured having, e.g., transfer electrodes positioned at the output ends of the vertical CCD shift registers that constitute the storage section 40s. These transfer electrodes can be driven independently from the storage section 40s. The transfer electrodes are arranged in different orders corresponding to, e.g., odd-numbered columns and even-numbered columns. The distribution section 40t can be driven so that the information-charge packets of each row output from the storage section 40s are separated into groups of information-charge packet groups of odd-numbered columns and groups of information-charge packets of even-numbered columns, and each group of the information-charge packets is transferred to the horizontal transfer section 40h, respectively.

The horizontal transfer section 40h comprises a horizontal CCD shift register. The information charges that were vertically transferred from the storage section 40s through the distribution section 40t are horizontally transferred to the output section 40d by the horizontal transfer section 40h.

The output section 40d is composed of an FD region, which constitutes an electrically isolated capacitance, and an amplifier for extracting changes in the electric potential of the FD region. The output section 40d receives the information charges output from the horizontal transfer section 40h in one-bit units on the FD region. The information charges are converted to voltage values and output as time-series image signals. The FD region is made to be smaller, e.g., than the channel width of the horizontal CCD shift register in order to reduce the associated capacity.

The horizontal CCD shift register that constitutes the horizontal transfer section 40h is composed of: a main portion 40m that contains bit groups positioned to correspond to the rows of the imaging section 40i or the storage section 40s; and a dummy portion 40e that is an extension from the output end of the main portion. The dummy portion 40e includes a portion composed of a sequence of transfer stages in which the width of the charge-transfer channel gradually decreases from the main portion 40m, which has a relatively large channel width, towards the FD region, which is small. The dummy portion 40e is capable of smoothly transferring the information charges.

The horizontal CCD shift register has a buried-channel structure. N-wells, i.e., N-type diffusion layers, are formed on P wells, i.e., P-type diffusion layers, which are formed within an N-type semiconductor substrate in the transfer-channel region of the horizontal CCD shift register. Transfer electrodes are arranged on the transfer-channel region in the row direction, which is the direction of charge transfer. The channel potentials are changed by transfer clocks that have a plurality of phases and that are applied to the transfer electrodes, whereby the information charges are transferred.

First poly-Si electrodes and second poly-Si electrodes are arranged in an alternating fashion on the transfer-channel region of the horizontal CCD shift register to act as transfer electrodes. A plurality of clock-signal lines for horizontal transfer are also positioned in parallel in the transfer-channel region. Electrode pairs composed of mutually adjoining first and second poly-Si electrodes are connected in sequence to the clock-signal lines. The main portion 40m and the dummy portion 40e are driven together by the transfer clocks, which are supplied by the clock-signal lines. The present CCD image sensor 40 is configured to be capable of six-phase driving in order to enable three-pixel addition in the horizontal transfer section 40h. Six clock-signal lines are correspondingly positioned. The plurality of electrode pairs aligned in the horizontal direction are connected in periods of six pairs to the same clock-signal lines. The electrode pairs corresponding to the transfer clocks φ₁ through φ₆ of the six phases will be designated as transfer electrodes HS1 through HS6, respectively. The transfer stages of the horizontal CCD shift register are configured from an electrode pair and an element region, which is the transfer-channel region below the electrode pair. The first poly-Si electrode is positioned on the downstream side of charge transfer in each transfer stage, and the transfer-channel region beneath the first poly-Si electrode forms a storage region. The second poly-Si electrode is positioned upstream from the first poly-Si electrode, and the transfer-channel region below the second poly-Si electrode forms a barrier region.

The barrier regions are formed by the ion implantation of boron or another P-type impurity in the N-wells. The barrier regions are established at a channel potential that is shallower than the storage regions by a barrier potential-difference φ_{B}. During the manufacturing process of the CCD image sensor 40, the ion implantation of impurities in order to form the barriers is performed using an ion-implantation mask formed on the substrate after N-wells has been formed into the transfer-channel regions of the CCD shift registers and the first poly-Si electrodes have been formed by patterning the first poly-Si layer laid on the substrate. This mask is formed by, e.g., patterning a photoresist applied to the substrate. After the barrier regions have been formed, the second poly-Si electrodes, interlayer insulating films, metal wiring, color filters, and the like are formed, and the CCD image sensor 40 is completed.

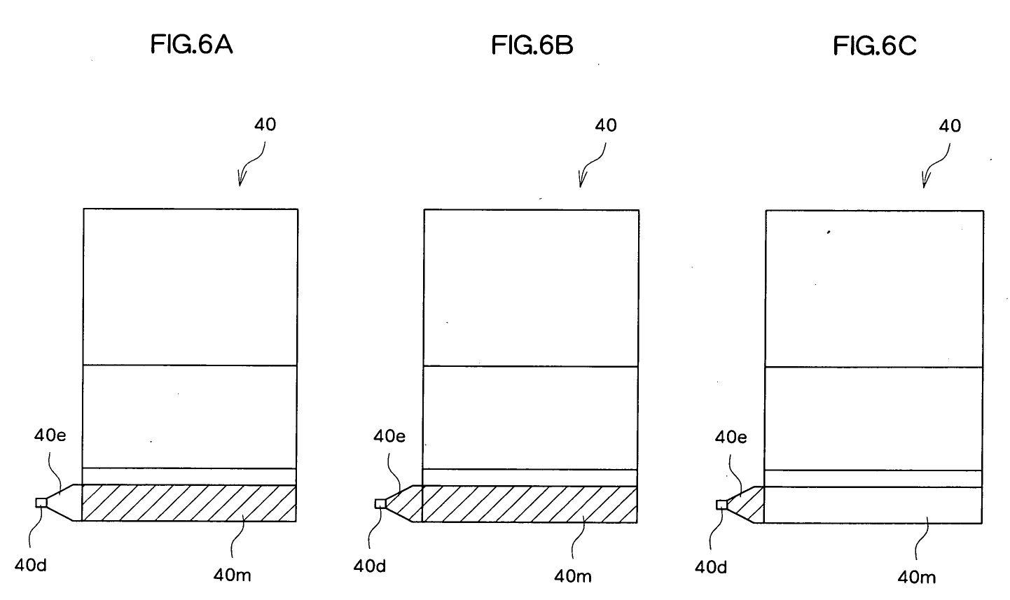

FIGS. 6A through 6C are schematic sectional top views of the image sensor and describe the steps for forming the barrier regions of the horizontal CCD shift register. The ion-implantation step for forming the barrier regions comprises the following steps A and B. Step B is performed after step A, for example, but the order of steps A and B may be changed.

(Step A) A photoresist pattern is formed on the substrate surface. The photoresist pattern has an aperture in the region corresponding to the main portion 40m (the region of diagonal lines in FIG. 6A). Ion implantation of P-type impurities is performed using this photoresist pattern as a mask.

(Step B) A photoresist pattern is formed on the substrate surface. The photoresist pattern has an aperture in the region corresponding to the main portion 40m and the dummy portion 40e (the region of diagonal lines in FIG. 6B). Ion implantation of P-type impurities is performed using this photoresist pattern as a mask.

Step A above may also be combined with step C below.

(Step C) A photoresist pattern is formed on the substrate surface. The photoresist pattern has an aperture in the region corresponding to the dummy portion 40e (the region of diagonal lines in FIG. 6C). Ion implantation of P-type impurities is performed using this photoresist pattern as a mask.

The first poly-Si electrodes within the mask aperture inhibit ion implantation in the N-wells during the steps A, B, C, and P-type impurities are therefore selectively introduced into the N-wells between the first poly-Si electrodes, whereupon the barrier regions are formed.

By combining step A and step B, P-type impurities can be implanted in the main portion 40m at a higher concentration than in the dummy portion 40e, and the barrier potential-difference φ_{B} in the main portion 40m (referred to below as φ_{BM}) can be set to a higher value than the barrier potential-difference φ_{B} in the dummy portion 40e (referred to below as φ_{BE}).

When combining steps A and C, the dose amount of ion implantation in step A is made to be larger than that of ion implantation in step C. The main portion 40m and the dummy portion 40e are configured so that the barrier potential-difference φ_{BM} remains greater than the barrier potential-difference φ_{BE}.

The barrier potential-differences φ_{BM} and φ_{BE} can be set according to the dose amount of ion implantation, as described above, but the barrier potential-differences may also change according to the extent of thermal diffusion of the implanted impurities or other factors. Accordingly, factors other than the dose amount of ion implantation are regulated, and the dose amount of ion implantation is set with these factors taken into account, allowing the relationship φ_{BM}>φ_{BE} to be obtained for the barrier potential-differences.

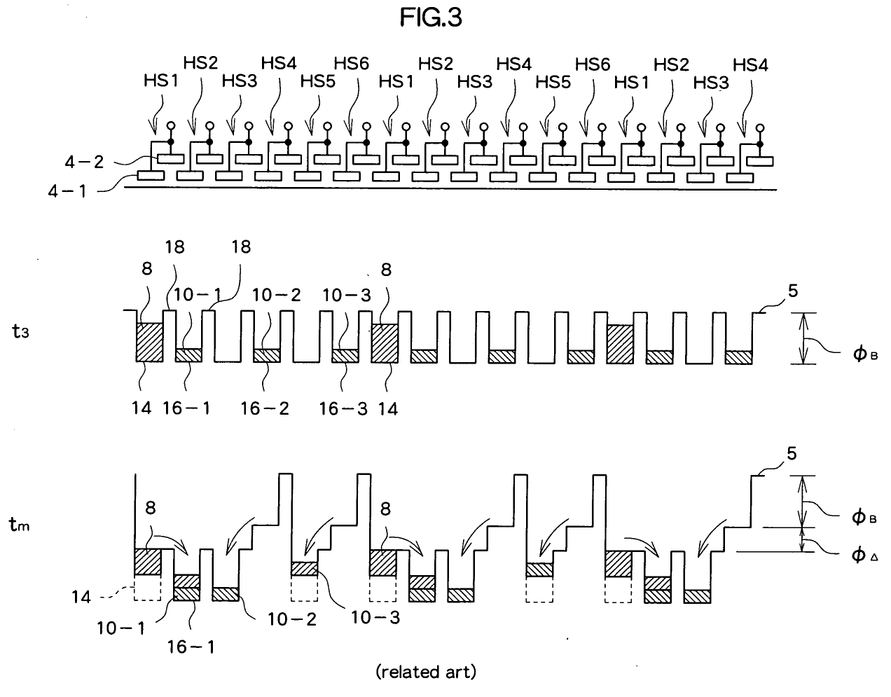

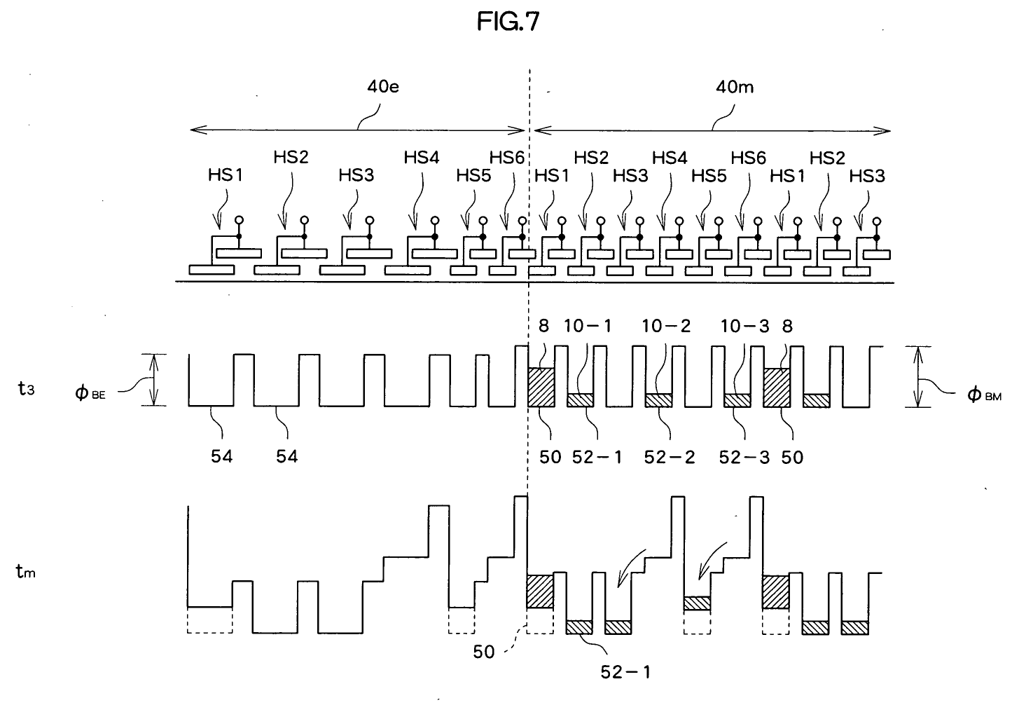

FIG. 7 is a schematic view for describing the aspects of the addition operation for the information charges of three pixels, which are arranged horizontally in the horizontal transfer section 40h. A row will be described in which information charges corresponding to R and information charges corresponding to G are aligned in an alternating fashion. FIG. 7 is contrasted with FIG. 3, which was given in relation to the prior art, and the layout of FIG. 7 essentially identical to FIG. 3. Specifically, FIG. 7 shows the storage state of the information charges and the channel potentials below the transfer electrodes HS1 through HS6 at time t₃, in which G information charges 10 of the even-numbered columns are read to the main portion 40m, and at time tₘ during the process of adding together the G information charges 10-1 through 10-3 that were read at time t₃. FIG. 7 also shows aspects of the dummy portion 40e in addition to the main portion 40m. The right side of the dotted line in FIG. 7 is the main portion 40m, and the left side is the dummy portion 40e. FIG. 7 also reflects the fact that the channel length of the storage regions in the transfer stages corresponding to HS1 through HS4 of the dummy portion 40e is made longer than in the other transfer stages in response to the transfer-channel width being made shorter than in the main portion 40m.

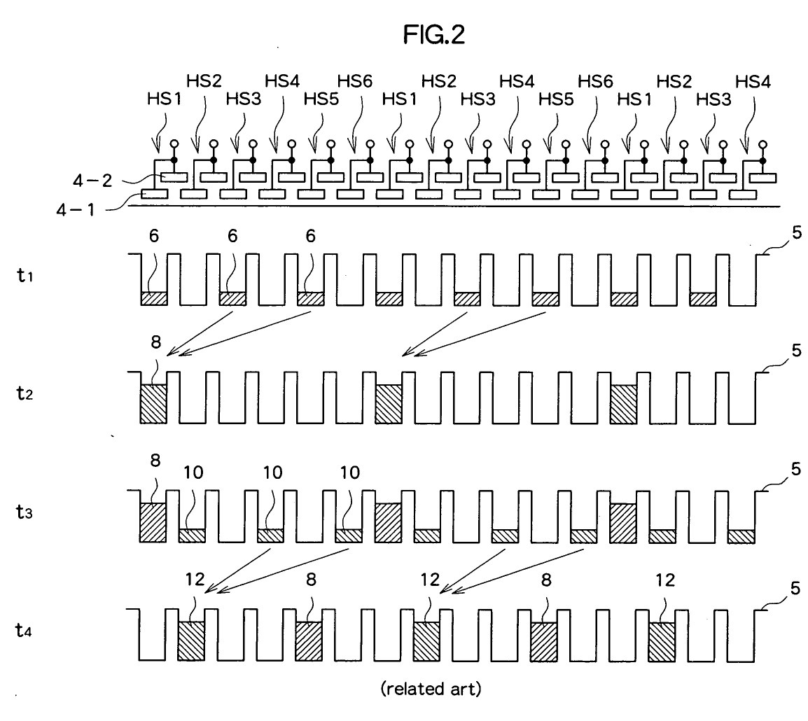

The outline of the operation for horizontal three-pixel addition is identical to that described using FIG. 2. Specifically, after information charges of odd-numbered columns R are read to the main portion 40m by the distribution section 40t (time t₁ in FIG. 2), the R information charges are added together in groups of three (time t₂ in FIG. 2). Information charges of even-numbered columns G are then read to the main portion 40m (time t₃ in FIG. 2). The state at time t₃ in FIG. 7 is equivalent to state at time t₃ in FIG. 2. Specifically, at time t₃, the additively synthesized R information charges 8 are stored in the main portion 40m in potential wells 50 below HS1, and the G information charges 10-1 through 10-3 are stored in the main portion 40m in potential wells 52-1 through 52-3 below HS2, HS4, HS6, respectively.

Since φ_{BM} is set to be larger than φ_{BE}, as described above, the potential wells 50 and 52-1 through 52-3 in the main portion 40m are deeper than potential wells 54 in the dummy portion 40e. The barrier potential-difference below the transfer electrodes HS6, which are the next transfer stages after the transfer electrodes HS1, which are the final transfer stages in the main portion 40m, is set to a value, e.g., IBM, that is larger than φ_{BE} so that the potential wells 50 below the transfer electrodes HS1 will have an adequate ability to store the added R information charges 8.

The state at time tₘ shown in FIG. 7 corresponds to the state at time tₘ in FIG. 3. At time tₘ, the transfer clocks applied to HS4 and HS6 have been changed from an on-voltage to an off-voltage, whereby the channel potentials below HS4 and HS6 become shallower and an electric potential gradient is formed from the storage regions below HS4 and HS6 towards the potential wells below HS3 and HS5. The information charges 10-2, 10-3 in the main portion 40m thereby move to the potential wells below HS3 and HS5.

The potential wells 50 that store the R information charges 8 that were additively synthesized below HS1 also become shallower in accordance with the change in the channel potential below HS6 during the movement operation of the information charges 10-2, 10-3 at time tₘ due the coupling capacitance between the transfer electrodes. However, since the barrier potential-difference φ_{BM} has been set to be large in the main portion 40m, as described above, the R information charges 8 stored in the potential wells 50 can be retained in the potential wells 50 without overflowing into the adjoining potential wells 52-1. In other words, the R information charges of the potential wells 50 and the G information charges of the potential wells 52-1 are prevented from mixing, and color mixing is minimized.

Information charges are not subjected to addition operations in the dummy portion 40e during the horizontal addition operation. Color mixing will therefore not occur in the dummy portion 40e during this operation even if the barrier potential-difference φ_{BE} of the dummy portion 40e is set to a value lower than the barrier potential-difference φ_{BM} of the main portion 40m.

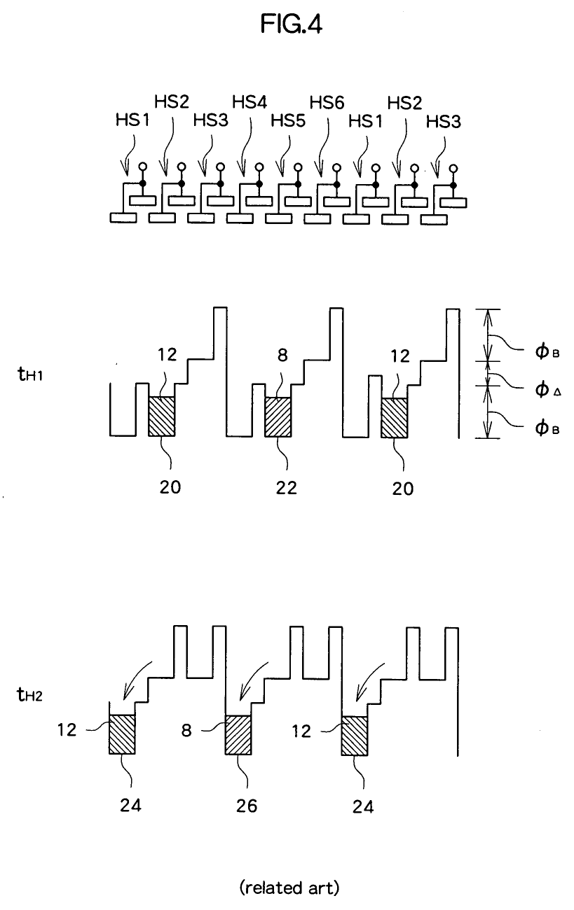

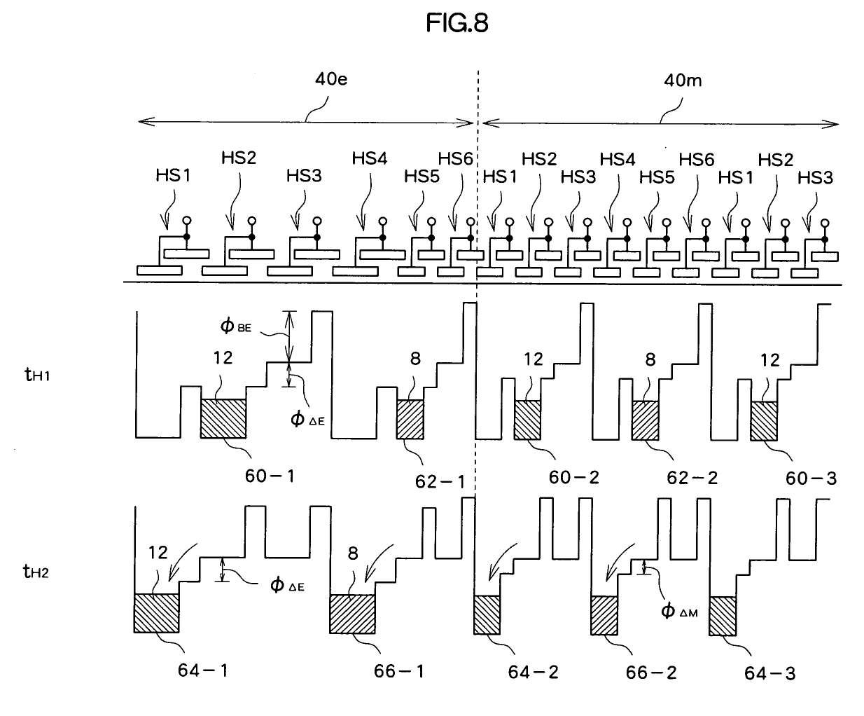

FIG. 8 is a schematic view for describing the aspects of the high-speed horizontal transfer operation in the horizontal transfer section 40h. FIG. 8 is contrasted with FIG. 4, which was given in relation to the prior art, and the layout of FIG. 8 essentially identical to FIG. 4. The high-speed horizontal transfer operation is initiated in a state in which the horizontal addition operation has completed after time tₘ in FIG. 7. Specifically, the state upon the initiation of the high-speed horizontal transfer operation is the same as the state at time t₄ in FIG. 2; i.e., a state in which the R information charges 8 and the G information charges 12 are alternatingly stored in every third potential well of the main portion 40m.

The high-speed horizontal transfer operation is performed by three-phase driving, wherein the transfer clocks φ₁ and φ₄ are the first phase, φ₂ and φ₅ are the second phase, and φ₃ and φ₆ are the third phase. The amplitude of the transfer clocks φ₁ through φ₆ may be the same as during the horizontal addition operation.

FIG. 8 shows the storage states of the information charges and the channel potentials below the transfer electrodes HS1 through HS6 at respective points in time before and after the movement of the information charges in the horizontal CCD shift register that is driven in three phases. Like FIG. 7, FIG. 8 also shows aspects of the dummy portion 40e in addition to the main portion 40m. The right side of the dotted line in FIG. 8 is the main portion 40m, and the left side is the dummy portion 40e. The fact that the storage regions in the transfer stages corresponding to HS1 through HS4 of the dummy portion 40e are configured to be larger than the other transfer stages is also as described in relation to FIG. 7. At time t_{H1} in FIG. 8, φ₁, φ₂, φ₄, and φ₅ are in an on-voltage state, φ₃ and φ₆ are in an off-voltage state, the G information charges 12 are stored in potential wells 60 below HS2, and the R information charges 8 are stored in potential wells 62 below HS5. At time t_{H2}, φ₂ and φ₅ change from the state at time t_{H1} to an off-voltage state, and the channel potentials become shallower in the storage regions below HS2, HS5, which had been in the state of potential wells. A channel potential gradient is thereby formed from the storage regions below HS2 towards potential wells 64 formed in the storage regions below HS1, and the information charges 12 move from the storage regions below HS2 to the potential wells 64. A channel potential gradient is also formed from the storage regions below HS5 towards potential wells 66 formed in the storage regions below HS4, and the information charges 8 move from the storage regions below HS5 to the potential wells 66.

In the dummy portion 40e, the channel-potential difference φ_{ΔE}, which is the difference in channel potential between the storage regions below transfer electrodes to which an off-voltage has been applied and the barrier regions below transfer electrodes to which an on-voltage has been applied, increases in relation to the extent that the barrier potential-difference φ_{BE} is decreased, as described above. The fringe electric field in the dummy portion 40e can thereby be ensured, and good transfer efficiency can be realized in the dummy portion 40e even though the transfer length of the information charges in the dummy portion 40e may be longer than the transfer length in the main portion 40m when the aforedescribed information charges 12 move to the potential wells 64 and the information charges 8 move to the potential wells 66. By increasing the barrier potential-difference φ_{BM} in the main portion 40m, the channel-potential difference φ_{ΔM}, which is the difference in channel potential between the storage regions below transfer electrodes to which an off-voltage has been applied and the barrier regions below transfer electrodes to which an on-voltage has been applied, becomes smaller than φ_{ΔE} in the dummy portion 40e. However, the transfer length is also shorter than in the dummy portion 40e, and transfer efficiency can therefore be ensured. Transfer efficiency during horizontal transfer operations at high speeds can thus be ensured in the dummy portion 40e as well as the main portion 40m, whereby color mixing resulting from information charges that remain after the transfer can be minimized.

The operation of the present invention was described above using the example in FIGS. 7 and 8, wherein rows in which R and G information charges were aligned in alternation were used as the rows which are read from the storage section 40s to the horizontal transfer section 40h, but the operation for rows in which G and B information charges are aligned in alternation is also essentially the same.

An example configuration was described in the present embodiment in which the concentration of P-type impurities in the first-stage barrier regions (the barrier concentration) of the dummy portion 40e is the same as in the main portion 40m. A boundary that provides a difference in barrier concentration is thus not needed for precise alignment of the boundary between the main portion 40m and the dummy portion 40e. In a configuration in which, e.g., a plurality of transfer stages having the same channel width as the main portion 40m are positioned towards the main portion 40m in the dummy portion 40e, the dummy portion, which should provide a difference in barrier concentration relative to the main portion 40m, is actually a transfer stage in which the channel width becomes smaller than in the main portion 40m due to the reasons explained in the paragraph concerning the problems the present invention is intended to solve. Specifically, the transfer stages in the dummy portion 40e that have the same channel width as the main portion 40m are formed at a barrier concentration shared by the main portion 40m in this case. The boundary that provides the difference in barrier concentrations can be established at the position within the dummy portion 40e at which the channel width begins to decrease towards the FD region. On the other hand, in cases such as when an optical black region is provided to the imaging section 40i, information charges may not be substantially transferred from the storage section 40s, and the potential wells of the transfer stages near the output end of the main portion 40m may be kept empty during the horizontal addition process. A configuration may be used in such instances wherein the barrier-potential difference in the first stage of the dummy portion 40e is kept from being high.

The barrier potential-differences φ_{BM} and φ_{BE} are established while taking into account the amplitude of the transfer clocks and the amount of charge stored. Specifically, the barrier potential differences are set to be smaller than the shift amount of the channel potentials of the storage regions between the application of an on-voltage by the transfer clocks and the application of an off-voltage by the transfer clocks. The barrier potential differences are set in this manner in order to avoid inadequate transfer during the horizontal transfer of information charges. The barrier potential-difference φ_{BE} of the dummy portion 40e is also established so that the ability of the storage regions to store charge is, e.g., equal to or greater than the volume of the information charges resulting from additive synthesis in the horizontal direction.

The horizontal shift register of the present embodiment was driven using six-phase transfer clocks in order for the information charges transferred from the storage section 40s to the horizontal transfer section 40h via the distribution section 40t to be added in groups of three pixels in the horizontal direction. However, the number of transfer clocks is not limited to six phases. The number of transfer clocks used may be changed as appropriate in accordance with the number of pixels of the added information charges.

A solid-state image sensor according to the present invention as described above comprises a plurality of vertical CCD shift registers that are arranged in a row direction for transferring in a column direction information charges generated according to incident light; a horizontal CCD shift register for transferring in the row direction the information charges output from the vertical CCD shift registers, in which a charge-transfer region is formed from a plurality of element regions arranged in the row direction, and in which adjoining element regions can, independently of one another, control a channel potential using a transfer clock; and an output section for converting the information charges output from the horizontal CCD shift register into voltage signals. The element regions of the horizontal CCD shift register have a storage region positioned on a downstream side of charge transfer, and a barrier region positioned on an upstream side thereof and having a channel potential that is shallower than in the storage region. The horizontal CCD shift register has a main portion having a bit group connected to output ends of the plurality of vertical CCD shift registers; and an extension portion for transferring to the output section the information charges output from the main portion; and the channel potential of the barrier region is different in the main portion and in the extension portion.

The main portion and the extension portion of the horizontal CCD shift register have different channel potentials in the barrier region and can be driven by the shared transfer clock, as described in the embodiment above.

As described in the embodiment above, the element regions of the horizontal CCD shift register can be arranged in the main portion in the row direction at a pitch corresponding to spaces in the row direction in the vertical CCD shift registers, and can be arranged in the extension portion in the row direction at a pitch that is larger than the pitch in the main portion.

A channel-potential difference between the storage region and the barrier region in the main portion of a solid-state image sensor having the above configuration is preferably set to be larger than the channel-potential difference in the extension portion.

A solid-state image sensor having the above configuration may also be configured so that the horizontal CCD shift register comprises an buried channel structure in which a surface layer, which has a first electrically conductive impurity and is positioned on a surface of a semiconductor substrate on the charge-transfer region, and a substrate layer, which has a second electrically conductive impurity and is positioned below the surface layer, are formed on both the main portion and the extension portion, a barrier impurity composed of the second electrically-conductive impurity is also introduced into the surface layer of the barrier region, and a concentration of the barrier impurity is established to be higher in the main portion than in the extension portion.

According to the present invention, different values are established for the difference in impurity concentration between the barrier regions and the storage regions below the transfer electrodes of the main portion of the horizontal CCD shift register, and the difference in impurity concentration between the barrier regions and the storage regions below the transfer electrodes of the extension portion. According to this configuration of a solid-state image sensor, the barrier potential-difference φ_{B} can be ensured in the main portion, and the fringe electric field can be ensured in the extension portion. As a result, contamination from information charges other than those to be subjected to additive synthesis can be prevented during the additive synthesis operation for the information charges in the horizontal CCD shift register. Improvements in horizontal resolution are therefore achieved while improvements in image quality are also achieved due to minimized color mixing in the solid-state image sensor on which a color filter is mounted. Meanwhile, decreases in transfer efficiency are minimized in the extension portion, and contamination of subsequent information charges with information charges that remain after the transfer can be minimized. High-speed horizontal transfer operation is therefore enabled, and improvements in horizontal resolution are achieved as well as improvements in image quality due to minimized color mixing.

1. A solid-state image sensor comprising:
a plurality of vertical CCD shift registers that are arranged in a row direction for transferring in a column direction information charges generated according to incident light;
a horizontal CCD shift register for transferring in the row direction the information charges output from the vertical CCD shift registers, in which a charge-transfer region is formed from a plurality of element regions arranged in the row direction, and in which adjoining element regions can, independently of one another, control a channel potential using a transfer clock; and
an output section for converting the information charges output from the horizontal CCD shift register into voltage signals, wherein
the element regions have a storage region positioned on a downstream side of charge transfer, and a barrier region positioned on an upstream side thereof and having a channel potential that is shallower than in the storage region;
the horizontal CCD shift register has a main portion having a bit group connected to output ends of the plurality of vertical CCD shift registers, and an extension portion for transferring to the output section the information charges output from the main portion; and
the channel potential of the barrier region is different in the main portion and in the extension portion.

2. The solid-state image sensor of claim 1, wherein the main portion and the extension portion of the horizontal CCD shift register can be driven by the shared transfer clock.

3. The solid-state image sensor of claim 1, wherein the element regions are arranged in the main portion in the row direction at a pitch corresponding to spaces in the row direction in the vertical CCD shift registers, and are arranged in the extension portion in the row direction at a pitch that is larger than in the main portion.

4. The solid-state image sensor of claim 1, wherein
a channel-potential difference between the storage region and the barrier region in the main portion is set to be larger than the channel-potential difference in the extension portion.

5. The solid-state image sensor of claim 1, wherein
the horizontal CCD shift register comprises an buried channel structure in which a surface layer, which has a first electrically conductive impurity and is positioned on a surface of a semiconductor substrate on the charge-transfer region, and a substrate layer, which has a second electrically conductive impurity and is positioned below the surface layer, are formed on both the main portion and the extension portion;
a barrier impurity composed of the second electrically-conductive impurity is also introduced into the surface layer of the barrier region; and
a concentration of the barrier impurity is established to be higher in the main portion than in the extension portion.
